(19) United States
(12) Patent Application Publication
(10) Pub. No.: US 2023/0377653 A1
(43) Pub. Date: Nov. 23, 2023

(54) Memory Arrays Comprising Strings Of Memory Cells And Methods Used In Forming A Memory Array Comprising Strings Of Memory Cells

(71) Applicant: Micron Technology, Inc., Boise, ID (US)

(72) Inventors: Alyssa N. Scarbrough, Boise, ID (US); John D. Hopkins, Meridian, ID (US); Jordan D. Greenlee, Boise, ID (US)

(73) Assignee: Micron Technology, Inc., Boise, ID (US)

(21) Appl. No.: 17/747,166

(22) Filed: May 18, 2022

(51) Int. Cl. G11C 16/04; H01L 27/11519; H01L 27/11556; H01L 27/11565; H01L 27/11582

(52) U.S. Cl. CPC G11C 16/0483; H01L 27/11519; H01L 27/11556; H01L 27/11565; H01L 27/11582

(57) ABSTRACT

A memory array comprising strings of memory cells comprises laterally-spaced memory blocks individually comprising a first vertical stack comprising vertically-alternating insulative tiers and conductive tiers. Strings of memory cells comprise channel-material strings that extend through the insulative tiers and the conductive tiers. A second vertical stack is aside the first vertical stack. The second vertical stack comprises an upper portion directly above a lower portion. The upper portion comprises vertically-alternating tiers that are of different composition relative one another. The lower portion comprises dummy plugs that comprise metal oxide directly above metal material. The metal oxide and the metal material comprise different compositions relative one another. Other embodiments, including method, are disclosed.

### TECHNICAL FIELD

Embodiments disclosed herein pertain to memory arrays comprising strings of memory cells and to methods used in forming a memory array comprising strings of memory cells.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region therebetween. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIGS. 1-3 are diagrammatic cross-sectional views of portions of a construction that will comprise an array of elevationally-extending strings of memory cells in accordance with an embodiment of the invention.

FIGS. 4-41 are diagrammatic sequential sectional and/or enlarged views of the construction of FIGS. 1-3, or portions thereof or alternate and/or additional embodiments, in process in accordance with some embodiments of the invention.

### DETAILED DESCRIPTION OF EXAMPLE EMBODIMENTS

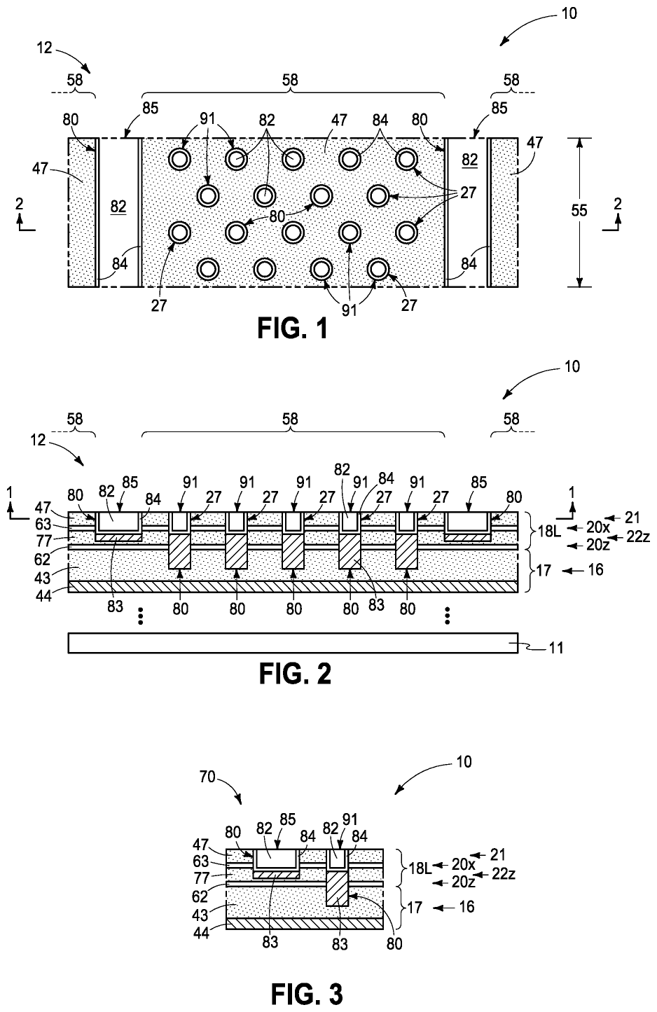

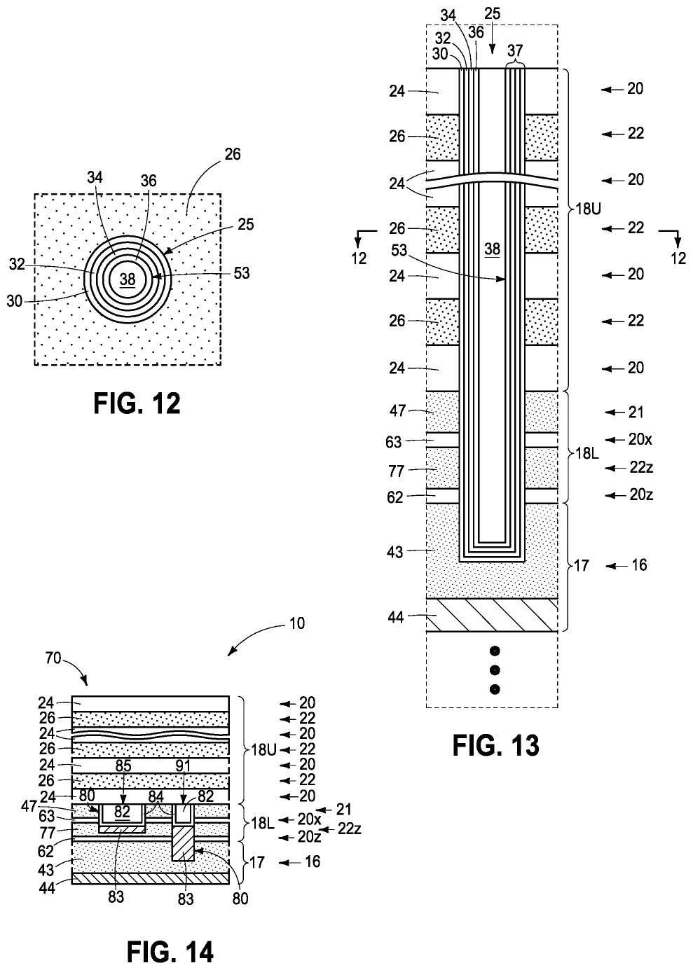

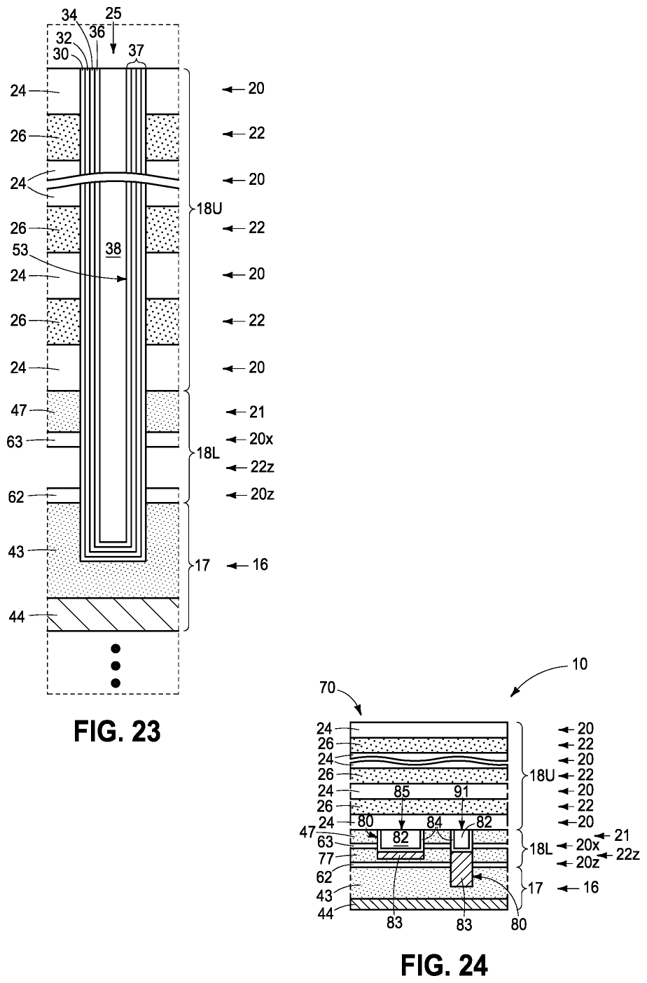

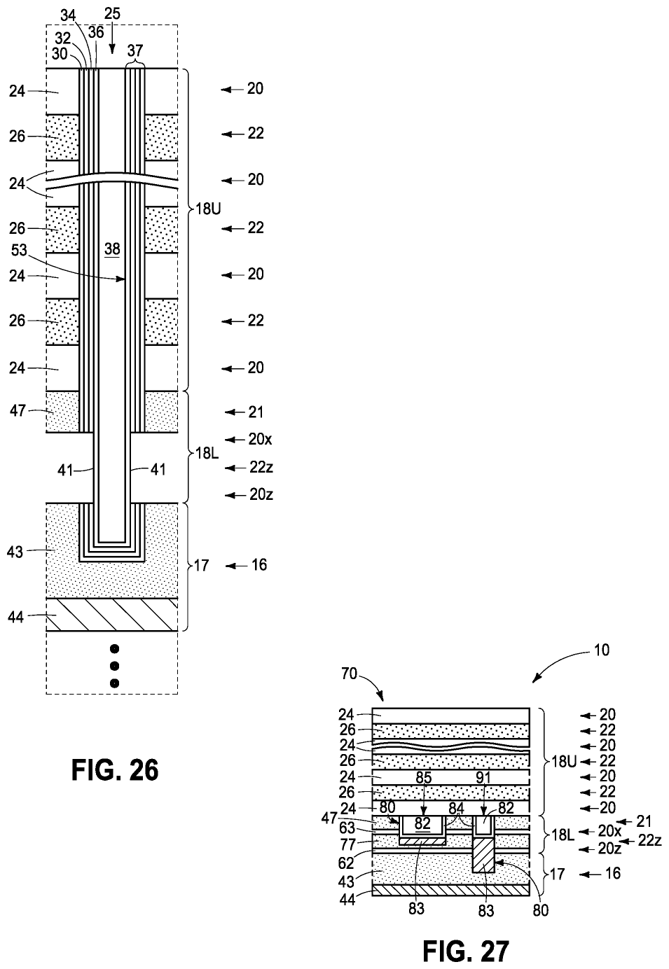

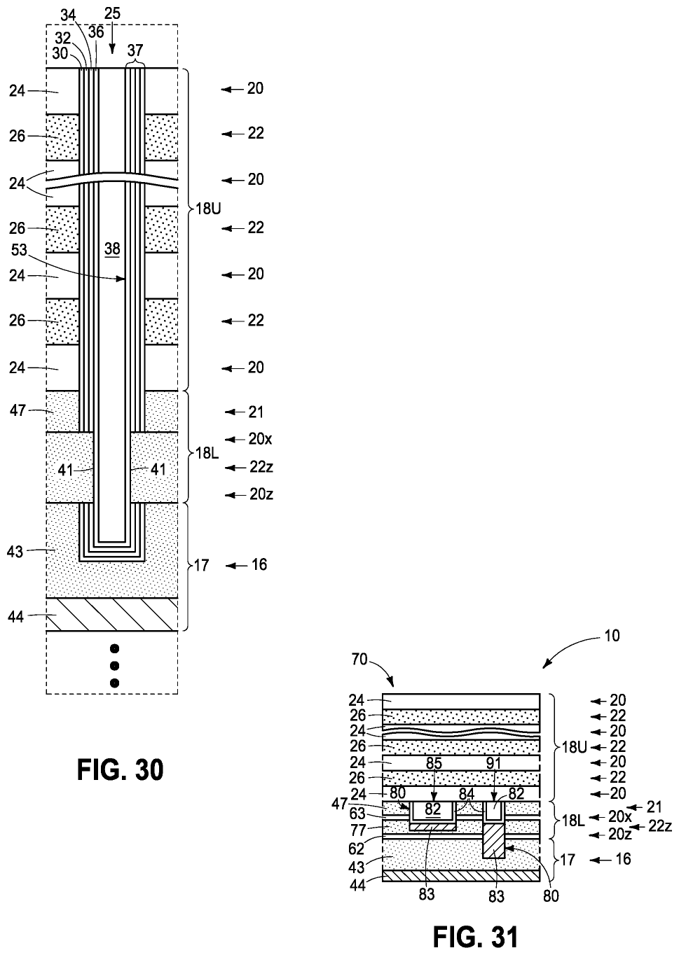

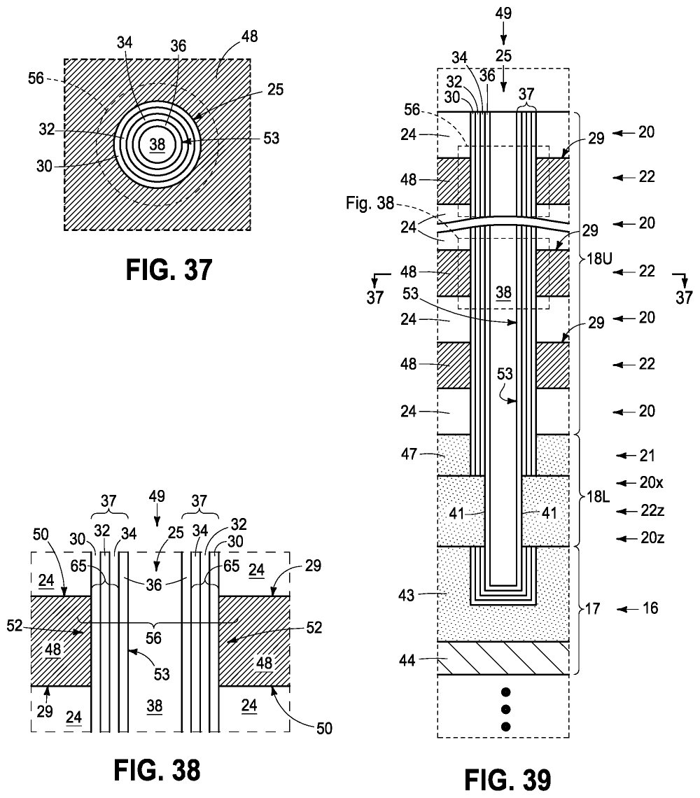

Embodiments of the invention encompass methods used in forming a memory array, for example an array of NAND or other memory cells having peripheral control circuitry under the array (e.g., CMOS-under-array). Embodiments of the invention encompass so-called “gate-last” or “replacement-gate” processing, so-called “gate-first” processing, and other processing whether existing or future-developed independent of when transistor gates are formed. Embodiments of the invention also encompass a memory array (e.g., NAND architecture) independent of method of manufacture. Example method embodiments are described with reference to FIGS. 1-41 which may be considered as “gate-last” or “replacement-gate” processing. Further, and regardless, the following sequence of processing steps is but one example and other sequences of the example processing steps (with or without other processing steps) may be used regardless of whether using “gate-last/replacement-gate” processing.

FIGS. 1-3 show a construction 10 having an array or array area 12 in which elevationally-extending strings of transistors and/or memory cells will be formed. Construction 10 comprises a base substrate 11 having any one or more of conductive/conductor/conducting, semiconductive/semiconductor/semiconducting, or insulative/insulator/insulating (i.e., electrically herein) materials. Various materials have been formed elevationally over base substrate 11. Materials may be aside, elevationally inward, or elevationally outward of the FIGS. 1-3-depicted materials. For example, other partially or wholly fabricated components of integrated circuitry may be provided somewhere above, about, or within base substrate 11. Control and/or other peripheral circuitry for operating components within an array (e.g., array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

In one embodiment, a conductor tier 16 comprising conductor material 17 has been formed above substrate 11. Conductor material 17 as shown comprises upper conductor material 43 directly above and directly electrically coupled to (e.g., directly against) lower conductor material 44 of different composition from upper conductor material 43. An example upper conductor material 43 comprises conductively-doped semiconductive material (e.g., n-type-doped or p-type-doped polysilicon). An example lower conductor material 44 comprises metal material (e.g., a metal silicide such as WSiₓ). Conductor tier 16 may comprise part of control circuitry (e.g., peripheral-under-array circuitry and/or a common source line or plate) used to control read and write access to the transistors and/or memory cells that will be formed in array 12.

A lower portion 18L of a stack 18* has been formed directly above conductor tier 16 (when present) and substrate 11 (an * being used as a suffix to be inclusive of all such same-numerically-designated components that may or may not have other suffixes). Stack 18* will comprise vertically-alternating conductive tiers 22* and insulative tiers 20*. Lower portion 18L and conductor tier 16 collectively comprise laterally-spaced memory-block regions 58 that will comprise laterally-spaced memory blocks 58 in a finished circuitry construction. Memory-block regions 58 and resultant memory blocks 58 (not yet shown) may be considered as being longitudinally elongated and oriented, for example horizontally-parallel relative one another along a direction 55.

Conductive tiers 22* (alternately referred to as first tiers) may not comprise conducting material and insulative tiers 20* (alternately referred to as second tiers) may not comprise insulative material or be insulative at this point in processing in conjunction with the hereby initially-described example method embodiment which is “gate-last” or “replacement-gate”. In one embodiment, lower portion 18L comprises a lowest tier 20z of second tiers 20* directly above (e.g., directly against) conductor material 17. Example lowest second tier 20z is insulative and may be sacrificial (e.g., in array 12; e.g., comprising material 62, for example silicon dioxide and/or silicon nitride). A next-lowest second tier 20x of second tiers 20* is directly above lowest second tier 20z and may be sacrificial (e.g., in array 12; e.g., comprising material 63, for example silicon dioxide and/or silicon nitride). A lowest tier 22z of first tiers 22* comprising sacrificial material 77 (e.g., polysilicon or silicon nitride) is vertically between lowest second tier 20z and next-lowest second tier 20x. Example lower portion 18L comprises a conducting-material tier 21 comprising conducting material 47 (e.g., conductively-doped polysilicon) that is directly above next-lowest second tier 20x. Additional tiers may be present. For example, one or more additional tiers may be above tier 21 (tier 21 thereby not being the uppermost tier in portion 18L, and not shown), between tier 21 and 20x (not shown), and/or below tier 22z (other than 20z not being shown).

In some embodiments, construction 10 may be considered as comprising a first region (e.g., as shown by FIGS. 1 and 2) and a second region 70 aside the first region (e.g., as shown in FIG. 3). Second region 70 may be laterally-contacting the first region (not shown) or may be laterally-spaced from the first region (e.g., closely laterally there-adjacent but not touching, or laterally-far there-from and not touching). Second region 70 may be within one or more of the memory block regions (regardless of whether such memory block region[s] is/are circuit operative or circuit inoperative). In some embodiments, construction 10 may be considered as comprising a first vertical stack (e.g., stack 18* in FIG. 2) and a second vertical stack (e.g., stack 18* in second region 70).

In one embodiment, lower portion 18L comprises plugs 91 (islands) in locations 27 where individual channel-material strings will be formed. Plugs 91 comprising sacrificial material 80 that comprises metal oxide 82 directly above metal material 83. Metal oxide 82 and metal material 83 comprise different compositions relative one another. In one embodiment, metal material 83 comprises at least one of an elemental-form metal, a metal nitride, and a metal silicide (e.g., W, Ti, Co, Ta, a tungsten nitride, a titanium nitride, a cobalt nitride, a tantalum nitride, a tungsten silicide, a titanium silicide, a cobalt, silicide, a tantalum silicide, etc.). In one embodiment, metal material 83 comprises tungsten (i.e., regardless of form[s]). In one embodiment, metal material 83 comprises a metal oxide (albeit at least some portion thereof being of different composition from that of metal oxide 82; e.g., an aluminum oxide, a tungsten oxide, a hafnium oxide, a hafnium aluminum oxide, a tantalum oxide, etc.) and in another embodiment does not. In one embodiment, metal oxide 82 comprises at least one of an aluminum oxide, a tungsten oxide, a hafnium oxide, a hafnium aluminum oxide, and a tantalum oxide.

In one embodiment, metal oxide 82 is directly against metal material 83 (not shown; e.g., if material 84 were not there) and in another embodiment is not (as shown). Regardless, in one embodiment, insulator material 84 that is of different composition from that of metal oxide 82 and that of metal material 83 (e.g., silicon dioxide or silicon nitride) is between metal oxide 82 and metal material 83 and in one such embodiment and as shown metal oxide 82 and metal material 83 are everywhere separated by insulator material 84.

In one embodiment, rails 85 are individually between immediately-laterally-adjacent memory-block regions 58 (regardless of presence of plugs 91). Rails 85 comprise sacrificial material 80 that comprises metal oxide 82 directly above metal material 83. In one such embodiment, insulator material 84 is between metal oxide 82 and metal material 83 in rails 85 and, in one such latter embodiment, metal oxide 82 and the metal material 83 are everywhere separated by insulator material 84 in rails 85.

In one embodiment, plugs 91 and/or rails 85 are also formed in second region 70.

By way of example only, a way of forming plugs 91 and rails 85 comprises forming openings in lower portion 18L corresponding to depth and shape thereof (e.g., at the same time or at different times if both plugs 91 and rails 85 are to be formed). Metal material 83 is then formed in such openings and vertically recessed back. Insulator material 84 is then deposited as a liner in such openings, followed by formation of metal oxide 82 to overfill remaining volume of such openings and planarizing metal oxide 82 and insulator material 84 back at least to the top surface of lower portion 18L.

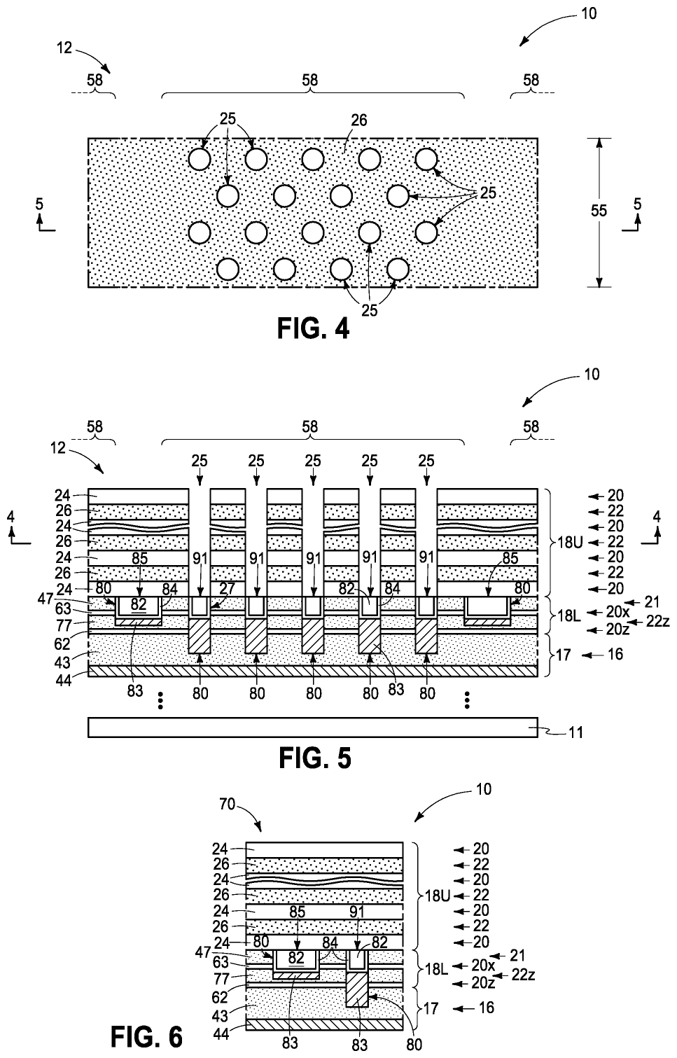

Referring to FIGS. 4-6, an upper portion 18U of stack 18* has been formed directly above lower portion 18L. Example upper portion 18U comprises vertically-alternating different composition first tiers 22 and second tiers 20. First tiers 22 may be conductive and second tiers 20 may be insulative, yet need not be so at this point of processing in conjunction with the hereby initially-described example method embodiment which is “gate-last” or “replacement-gate”. Example first tiers 22 and second tiers 20 comprise different composition materials 26 and 24, respectively (e.g., silicon nitride and silicon dioxide). Example upper portion 18U is shown starting above lower portion 18L with a second tier 20 although such could alternately start with a first tier 22 (not shown) or tier 21 may be considered as being in upper portion 18U (not so designated). Further, and by way of example, lower portion 18L may be formed to have one or more first and/or second tiers as a top thereof. Regardless, only a small number of tiers 20 and 22 is shown, with more likely upper portion 18U (and thereby stack 18*) comprising dozens, a hundred or more, etc. of tiers 20 and 22. Further, other circuitry that may or may not be part of peripheral and/or control circuitry may be between conductor tier 16 and stack 18*. By way of example only, multiple vertically-alternating tiers of conductive material and insulative material of such circuitry may be below a lowest of conductive tiers 22 and/or above an uppermost of conductive tiers 22. For example, one or more select gate tiers (not shown) may be between conductor tier 16 and lowest conductive tier 22 and one or more select gate tiers may be above an uppermost of conductive tiers 22. Alternately or additionally, at least one of the depicted uppermost and lowest conductive tiers 22 may be a select gate tier.

Channel openings 25 have been formed (e.g., by etching) through second tiers 20 and first tiers 22 in upper portion 18U to plugs 91 in lower portion 18L. Channel openings 25 may taper radially-inward (not shown) moving deeper into stack 18* (as may plugs 91 and/or rails 85, and not shown). Channel openings 25 may be of the same horizontal cross-sectional size and shape (as shown) where meeting with plugs 91 or may be of different one or both of horizontal cross-sectional size and shape (not shown). Channel openings 25 may be formed by etching materials 24 and 26 to stop on material 80 of plugs 91 (i.e., atop or within). In one embodiment comprising example second region 70, and as shown, channel openings 25 have not been there-formed to plugs 91.

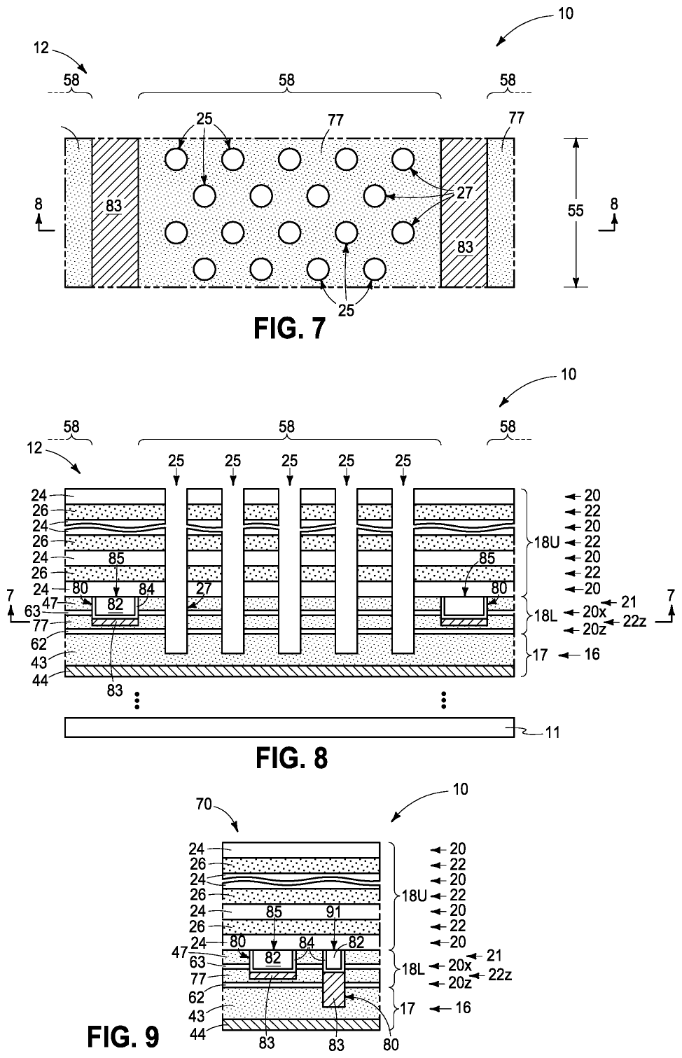

Referring to FIGS. 7-9, sacrificial material 80 of plugs 91 has been removed (e.g., by isotropic etching) through channel openings 25.

Transistor channel material may be formed in the individual channel openings elevationally along the insulative tiers and the conductive tiers, thus comprising individual channel-material strings, which is directly electrically coupled with conductor material in the conductor tier. Individual memory cells of the example memory array being formed may comprise a gate region (e.g., a control-gate region) and a memory structure laterally-between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells is elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) is laterally-between the channel material and the storage material.

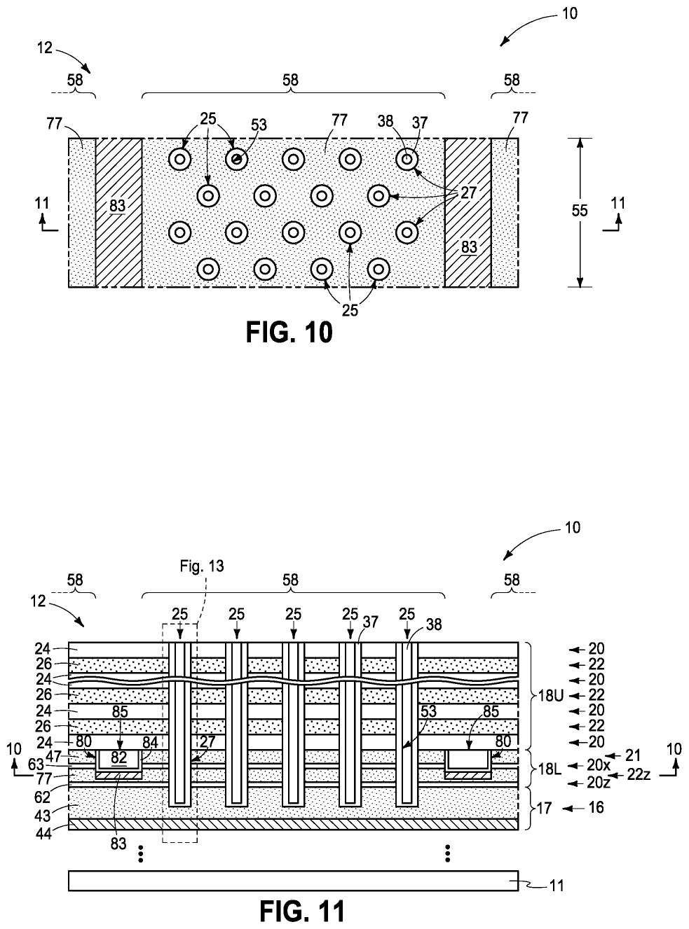

Referring to FIGS. 10-14, and in one embodiment as shown, charge-blocking material 30, storage material 32, and charge-passage material 34 have been formed in individual channel openings 25 elevationally along insulative tiers 20 and conductive tiers 22. Transistor materials 30, 32, and 34 (e.g., memory-cell materials) may be formed by, for example, deposition of respective thin layers thereof over stack 18* and in individual openings 25 followed by planarizing such back at least to a top surface of stack 18*.

Channel material 36 as a channel-material string 53 (e.g., an operative channel-material string) has also been formed in channel openings 25 elevationally along insulative tiers 20 and conductive tiers 22 in memory-block regions 58. Materials 30, 32, 34, and 36 are collectively shown as and only designated as material 37 in some figures due to scale. Example channel materials 36 include appropriately-doped crystalline semiconductor material, such as one or more silicon, germanium, and so-called III/V semiconductor materials (e.g., GaAs, InP, GaP, and GaN). Example thickness for each of materials 30, 32, 34, and 36 is 25 to 100 Angstroms. Punch etching may be conducted to remove materials 30, 32, and 34 from the bases of channel openings 25 (not shown) to expose conductor tier 16 such that channel material 36 is directly against conductor material 17 of conductor tier 16. Such punch etching may occur separately with respect to each of materials 30, 32, and 34 (as shown) or may occur with respect to only some (not shown). Alternately, and by way of example only, no punch etching may be conducted and channel material 36 may be directly electrically coupled to conductor material 17 of conductor tier 16 only by a separate conductive interconnect (not yet shown). A radially-central solid dielectric material 38 (e.g., spin-on-dielectric, silicon dioxide, and/or silicon nitride) is shown in channel openings 25. Alternately, and by way of example only, the radially-central portion in channel openings 25 may include void space(s) (not shown) and/or be devoid of solid material (not shown).

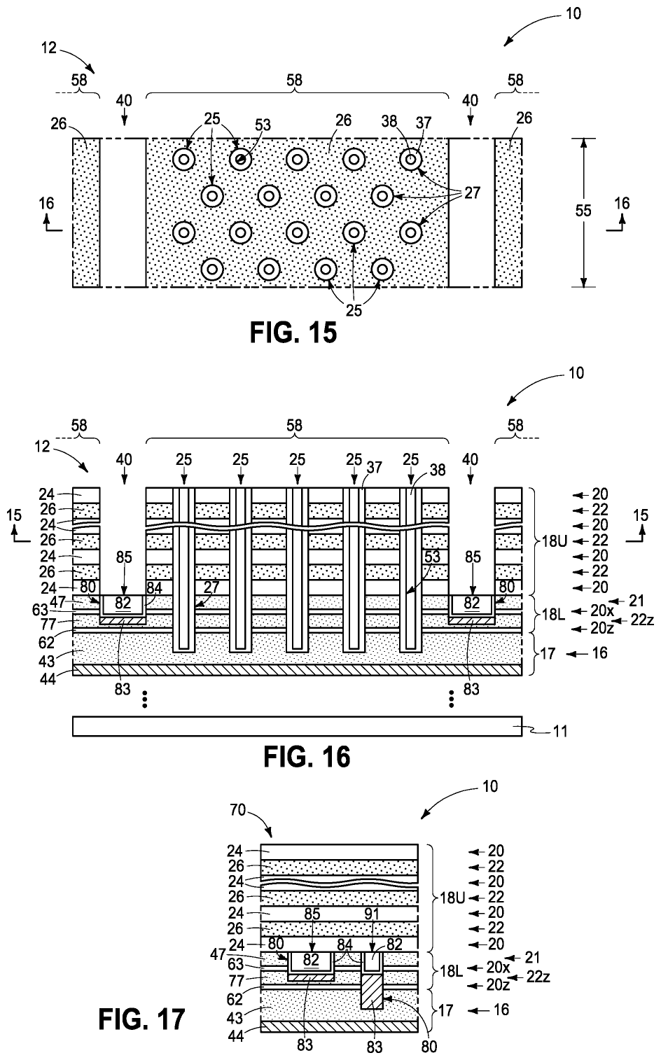

Referring to FIGS. 15-17, and in one embodiment, trenches 40 have been formed into upper portion 18U to rails 85. In one embodiment comprising example second region 70, such has not there-occurred. Trenches 40 may taper laterally-inward or laterally-outward moving deeper into stack 18 (not shown). By way of example and for brevity only, channel openings 25 are shown as being arranged in groups or columns of staggered rows of four and five channel openings 25 per row. Trenches 40 will typically be wider than channel openings 25 (e.g., 3 to 10 times wider). Any alternate existing or future-developed arrangement and construction may be used. Trenches 40 and channel openings 25 (and material formed therein) may be formed in any order relative the other or at the same time.

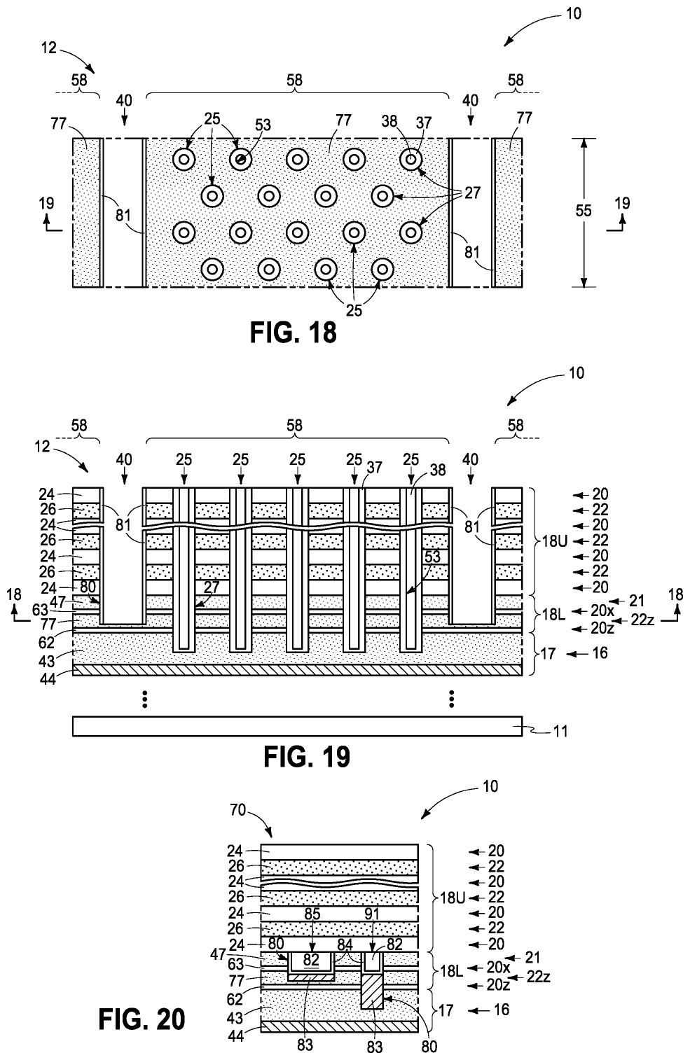

Referring to FIGS. 18-20, and in one embodiment, sacrificial material 80 of rails 85 has been removed (e.g., by isotropic etching) through trenches 40. An insulative liner 81 (e.g., hafnium oxide, aluminum oxide, multiple layers of silicon dioxide and silicon nitride, etc.) has been formed in trenches 40 followed by punch-etching there-through to expose material 77 therebelow.

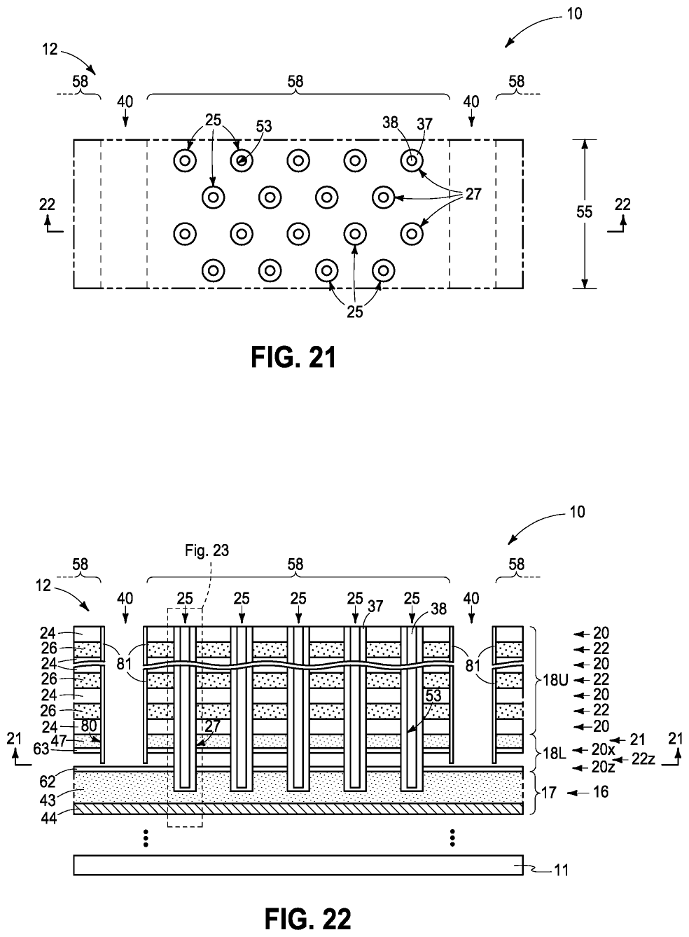

Referring to FIGS. 21-24, sacrificial material 77 (not shown) has been removed (e.g., by isotropic etching) from lowest first tier 22z through trenches 40. Such may occur, for example, by isotropic etching that is ideally conducted selectively relative to materials 62 and 63, for example using liquid or vapor H₃PO₄ as a primary etchant where material 77 is silicon nitride or using tetramethyl ammonium hydroxide [TMAH] where material 77 is polysilicon. Sacrificial material 77 may be removed from

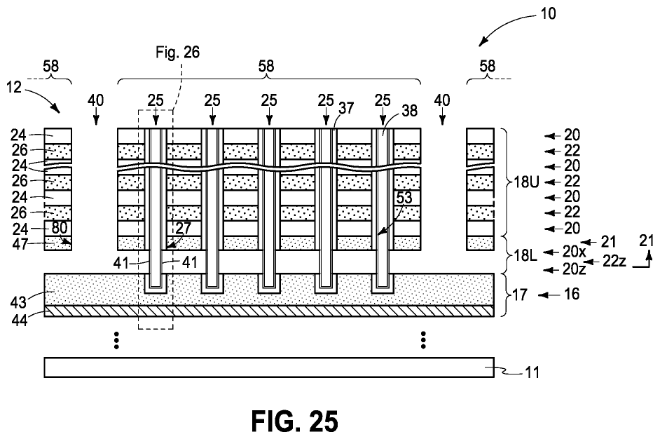

FIGS. 25-27 show example subsequent processing wherein, in one embodiment, material 30 (e.g., silicon dioxide), material 32 (e.g., silicon nitride), and material 34 (e.g., silicon dioxide or a combination of silicon dioxide and silicon nitride) have been etched in tier 22z to expose a sidewall 41 of channel material 36 of channel-material strings 53 in lowest first tier 22z. Any of materials 30, 32, and 34 in tier 22z may be considered as being sacrificial material therein. As an example, consider an embodiment where liner 81 (not shown) is one or more insulative oxides (other than solely silicon dioxide) and memory-cell materials 30, 32, and 34 individually are one or more of silicon dioxide and silicon nitride layers. In such example, the depicted construction can result by using modified or different chemistries for sequentially etching silicon dioxide and silicon nitride selectively relative to the other. As examples, a solution of 100:1 (by volume) water to HF will etch silicon dioxide selectively relative to silicon nitride, whereas a solution of 1000:1 (by volume) water to HF will etch silicon nitride selectively relative to silicon dioxide. Accordingly, and in such example, such etching chemistries can be used in an alternating manner where it is desired to achieve the example depicted construction. In one embodiment, such etching may be conducted selectively relative to liner 81 (when present, and liner 81 not being shown). In one embodiment and as shown, materials 62 and 63 (not shown) have been removed. When so removed, such may be removed when removing materials 30, 32, and 34 are removed, for example if materials 62 and 63 comprise one or both of silicon dioxide and silicon nitride. Alternately, when so removed, such may be removed separately (e.g., by isotropic etching). The artisan is capable of selecting other chemistries for etching other different materials where a construction as shown is desired. If liner 81 (not shown) comprises multiple layers of silicon dioxide and silicon nitride, such may be removed (e.g., by etching) commensurate with removal of materials 30, 32, 34, 62, and 63 where such collectively comprise silicon nitride and silicon dioxide. Alternately, liner 81 may remain at this point of processing (not shown) or be separately or otherwise removed.

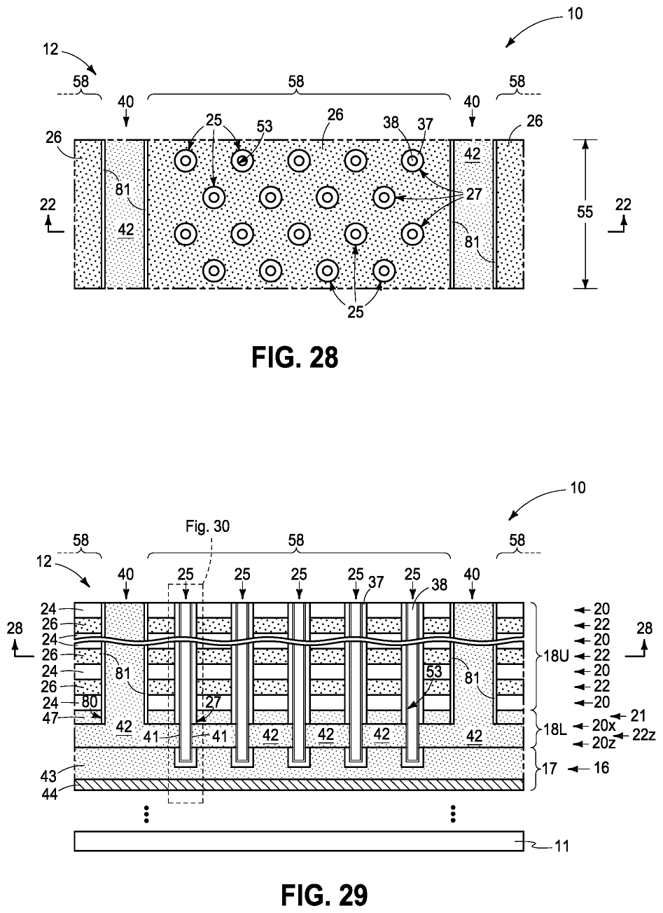

Referring to FIGS. 28-31, after exposing sidewall 41, conductive material 42 (e.g., conductively-doped polysilicon) has been formed in lowest first tier 22z and in one embodiment directly against sidewall 41 of channel material 36. In one embodiment and as shown, such has been formed directly against a bottom of conducting material 47 of conducting-material tier 21 and directly against a top of conductor material 43 of conductor tier 16, thereby directly electrically coupling together channel material 36 of individual channel-material strings 53 with conductor material 43 of conductor tier 16 and conducting material 47 of conducting-material tier 21.

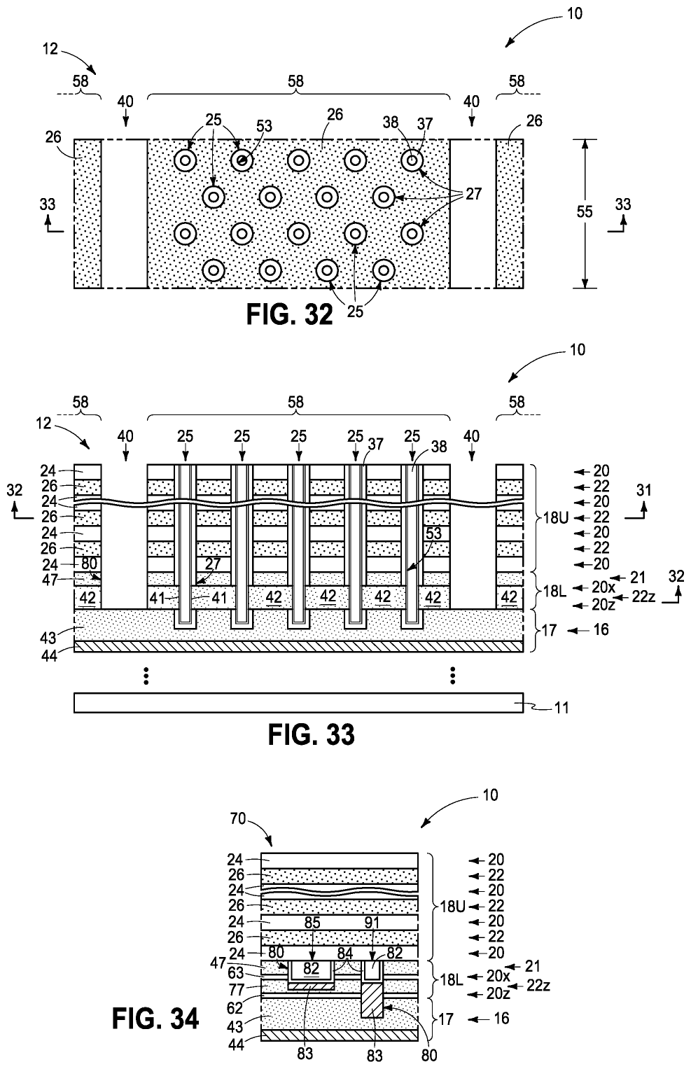

Referring to FIGS. 32-34, conductive material 42 has been removed from trenches 40 as has sacrificial liner 81 (not there-shown). Sacrificial liner 81 (when present) may be removed before or after forming conductive material 42. In one embodiment as shown, conducting material 47 of tier 21 and conductive material 42 of tier 22z being directly against one another may collectively be considered as the lowest conductive tier at least in array 12.

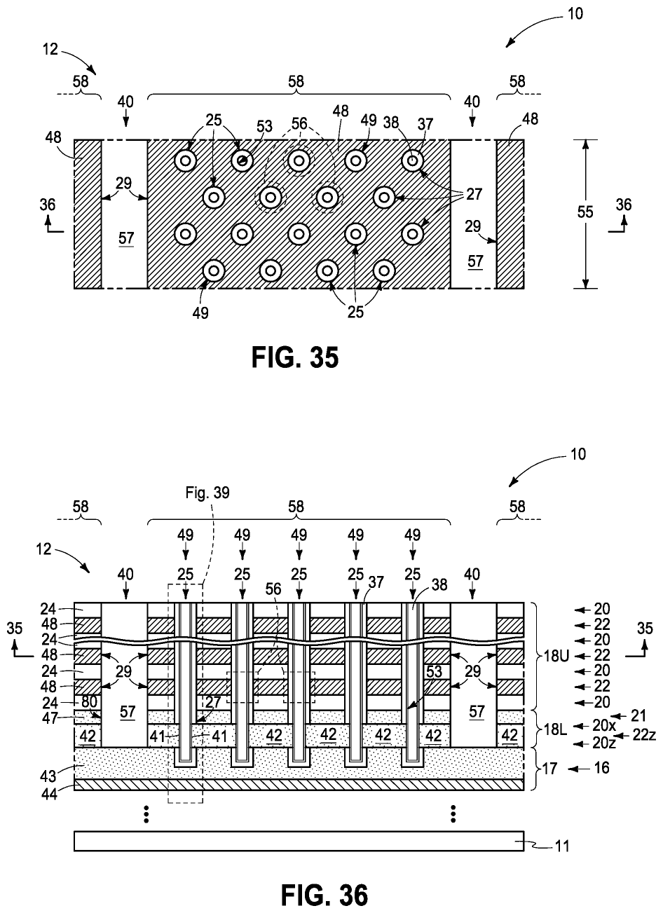

Referring to FIGS. 35-40, material 26 (not shown) of conductive tiers 22U has been removed, for example by being isotropically etched away through trenches 40 ideally selectively relative to the other exposed materials (e.g., using liquid or vapor H₃PO₄ as a primary etchant where material 26 is silicon nitride and other materials comprise one or more oxides or polysilicon). Material 26 (not shown) in conductive tiers 22U in the example embodiment is sacrificial and has been replaced with conducting material 48, and which has thereafter been removed from trenches 40, thus forming individual conductive lines 29 (e.g., wordlines) and elevationally-extending strings 49 of individual transistors and/or memory cells 56.

A thin insulative liner (e.g., Al₂O₃ and not shown) may be formed before forming conducting material 48. Approximate locations of some transistors and/or some memory cells 56 are indicated with a bracket or with dashed outlines, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conducting material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and channel material 36. In one embodiment and as shown with respect to the example “gate-last” processing, conducting material 48 of conductive tiers 22 is formed after forming openings 25 and/or trenches 40. Alternately, the conducting material of the conductive tiers may be formed before forming channel openings 25 and/or trenches 40 (not shown), for example with respect to “gate-first” processing.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and conducting material 48). Regardless, as an additional example, an interface of a storage material and conductive material of a control gate may be sufficient to function as a charge-blocking region in the absence of any separate-composition-insulator material 30. Further, an interface of conducting material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

Intervening material 57 has been formed in trenches 40 and thereby laterally-between and longitudinally-along immediately-laterally-adjacent memory blocks 58. Intervening material 57 may provide lateral electrical isolation (insulation) between immediately-laterally-adjacent memory blocks. Such may include one or more of insulative, semiconductive, and conducting materials and, regardless, may facilitate conductive tiers 22 from shorting relative one another in a finished circuitry construction. Example insulative materials are one or more of SiO₂, Si₃N₄, and Al₂O₃. Intervening material 57 may include through array vias (not shown).

In one embodiment, plugs 91 in second vertical stack 18* in second region 70 (only one being shown) are dummy plugs that remain in a finished circuitry construction that comprises memory array 12. In one embodiment, rails 85 in second vertical stack 18* in second region 70 (only one being shown) are dummy rails that remain in a finished circuitry construction that comprises memory array 12.

Any other attribute(s) or aspect(s) as shown and/or described herein with respect to other embodiments may be used.

Providing combination metal oxide/metal material etch-stop plugs and/or rails as disclosed herein may improve critical-dimension uniformity and/or better etch-stop function and/or reduce risk of over-etch when etching to plugs and/or rails.

FIGS. 1-40 show an example embodiment where, starting with FIGS. 7-9, the processing that has occurred in array or array region 12 (a first region or a first vertical stack) has not occurred in second region 70 but has so occurred as in FIGS. 1-6. However, aspects of the invention include some or all of the example processing of FIGS. 7+ occurring in second region 70. For example, and by way of examples only, in second region 70 any one or more of material 62 may be removed, material 63 may be removed, material 77 may be removed, material 42 may be formed, material 26 may be removed, material 48 may be formed, channel openings 25 may be formed, one or more of the materials in channel openings 25 may be formed, some or all of rails 85 may be removed, and some or all of plugs 91 may be removed.

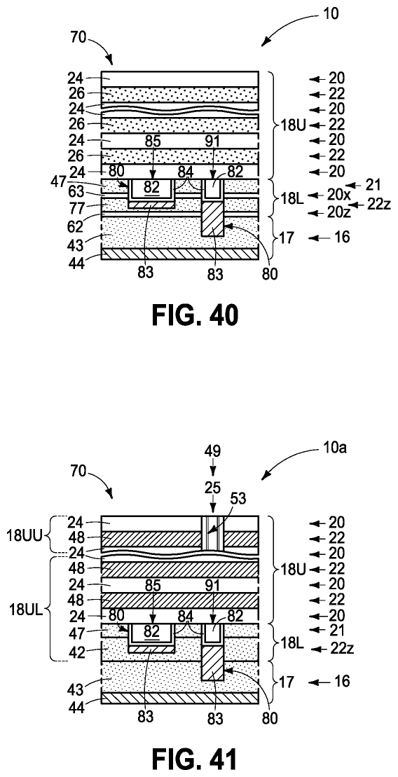

FIG. 41 shows an example alternate construction 10a. Like numerals from the above-described embodiments have been used where appropriate, with some construction differences being indicated with the suffix “a”. In some aspects, by way of example only, FIG. 41 differs from that of FIG. 40 in that materials 62, 63, and 26 have been removed (none thereby being shown) and materials 48 and 42 have been formed. Such may occur, for example, depending on location of second region 70 and proximity to trenches 40 (not shown in FIG. 41). Regardless, and in one embodiment, a dummy channel-material string 53 in FIG. 41 is directly above individual dummy plugs 91 (only one being shown), and in one such embodiment with dummy channel-material string 53 not extending to its dummy plug 91. Such may occur in a method embodiment, for example, if upper portion 18U is formed as two decks at different times, with each deck comprising multiple tiers 20 and 22, and with dummy channel-material strings 53 only being formed in an upper of such decks. Any other attribute(s) or aspect(s) as shown and/or described herein with respect to other embodiments may be used.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, a memory array (e.g., 12) comprising strings (e.g., 49) of memory cells (e.g., 56) comprises laterally-spaced memory blocks (e.g., 58) individually comprising a first vertical stack (e.g., 18* in FIG. 36) comprising vertically-alternating insulative tiers (e.g., 20) and conductive tiers (e.g., 22). Strings (e.g., 49) of memory cells (e.g., 56) comprising channel-material strings (e.g., 53) extend through the insulative tiers and the conductive tiers. A second vertical stack (e.g., 18* in FIG. 41) is aside the first vertical stack. The second vertical stack comprises an upper portion (e.g., 18UU) directly above a lower portion (e.g., 18UL). The upper portion comprises vertically-alternating tiers that are of different composition relative one another (e.g., 20, 22). The lower portion comprises dummy plugs (e.g., 91, only one being shown) that comprise metal oxide (e.g., 82) directly above metal material (e.g., 83). The metal oxide and the metal material comprise different compositions relative one another. Any other attribute(s) or aspect(s) as shown and/or described herein with respect to other embodiments may be used.

In one embodiment, a memory array (e.g., 12) comprising strings (e.g., 49) of memory cells (e.g., 56) comprises laterally-spaced memory blocks (e.g., 58) individually comprising a first vertical stack (e.g., 18* in FIG. 36) comprising vertically-alternating insulative tiers (e.g., 20) and conductive tiers (e.g., 22). Strings (e.g., 49) of memory cells (e.g., 56) comprising channel-material strings (e.g., 53) extend through the insulative tiers and the conductive tiers. A second vertical stack (e.g., 18* in FIG. 41) is aside the first vertical stack. The second vertical stack comprises an upper portion (e.g., 18UU) directly above a lower portion (e.g., 18UL). The upper portion comprises vertically-alternating tiers that are of different composition relative one another (e.g., 20, 22). The lower portion comprises dummy rails (e.g., 85) comprising metal oxide (e.g., 82) directly above metal material (e.g., 83). The metal oxide and the metal material comprise different compositions relative one another. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Herein, something is “dummy” if it is circuit-inoperative, meaning no current flow there-through even if the something is conductive and which may be a circuit inoperable dead end that is not part of a current flow path of a circuit even if extending to or from an electronic component.

Unless otherwise indicated, use of “or” herein encompasses either and both.

### CONCLUSION

In some embodiments, a method used in forming a memory array comprising strings of memory cells comprises forming a lower portion of a stack that will comprise vertically-alternating first tiers and second tiers on a substrate. The stack comprises laterally-spaced memory-block regions. The lower portion comprises plugs in locations where individual channel-material strings will be formed. The plugs comprise sacrificial material that comprises metal oxide directly above metal material. The metal oxide and the metal material comprise different compositions relative one another. The vertically-alternating first tiers and second tiers of an upper portion of the stack are formed directly above the lower portion. Material of the first tiers is of different composition from material of the second tiers. Channel openings are formed into the upper portion to the plugs. The sacrificial material of the plugs is removed through the channel openings and thereafter a channel-material string is formed in individual of the channel openings.

In some embodiments, a method used in forming a memory array comprising strings of memory cells comprises forming a lower portion of a stack that will comprise vertically-alternating first tiers and second tiers on a substrate. The stack comprises laterally-spaced memory-block regions. The lower portion comprises rails that are individually between immediately-laterally-adjacent of the memory-block regions. The rails comprise sacrificial material that comprises metal oxide directly above metal material. The metal oxide and the metal material comprise different compositions relative one another. The vertically-alternating first tiers and second tiers of an upper portion of the stack are formed directly above the lower portion. Material of the first tiers is of different composition from material of the second tiers. Trenches are formed into the upper portion to the rails and the sacrificial material of the rails is removed through the trenches. Channel-material strings are formed that extend through the first tiers and the second tiers in the memory-block regions.

In some embodiments, a memory array comprising strings of memory cells comprises laterally-spaced memory blocks individually comprising a first vertical stack comprising vertically-alternating insulative tiers and conductive tiers. Strings of memory cells comprise channel-material strings that extend through the insulative tiers and the conductive tiers. A second vertical stack is aside the first vertical stack. The second vertical stack comprises an upper portion directly above a lower portion. The upper portion comprises vertically-alternating tiers that are of different composition relative one another. The lower portion comprises dummy plugs that comprise metal oxide directly above metal material. The metal oxide and the metal material comprise different compositions relative one another.

In some embodiments, a memory array comprising strings of memory cells comprises laterally-spaced memory blocks individually comprising a first vertical stack comprising vertically-alternating insulative tiers and conductive tiers. Strings of memory cells comprise channel-material strings that extend through the insulative tiers and the conductive tiers. A second vertical stack is aside the first vertical stack. The second vertical stack comprises an upper portion directly above a lower portion. The upper portion comprises vertically-alternating tiers that are of different composition relative one another. The lower portion comprising dummy rails comprises metal oxide directly above metal material. The metal oxide and the metal material comprise different compositions relative one another.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming a memory array comprising strings of memory cells, comprising:
forming a lower portion of a stack that will comprise vertically-alternating first tiers and second tiers on a substrate, the stack comprising laterally-spaced memory-block regions, the lower portion comprising plugs in locations where individual channel-material strings will be formed, the plugs comprising sacrificial material that comprises metal oxide directly above metal material, the metal oxide and the metal material comprising different compositions relative one another;
forming the vertically-alternating first tiers and second tiers of an upper portion of the stack directly above the lower portion, material of the first tiers being of different composition from material of the second tiers;
forming channel openings into the upper portion to the plugs; and
removing the sacrificial material of plugs through the channel openings and thereafter forming a channel-material string in individual of the channel openings.

2. The method of claim 1 wherein the metal material comprises a metal oxide.

3. The method of claim 1 wherein the metal material does not comprise a metal oxide.

4. The method of claim 1 wherein the metal material comprises at least one of an elemental-form metal, a metal nitride, and a metal silicide.

5. The method of claim 1 wherein the metal oxide comprises at least one of an aluminum oxide, a tungsten oxide, a hafnium oxide, a hafnium aluminum oxide, and a tantalum oxide.

6. The method of claim 5 wherein the metal oxide comprises aluminum oxide.

7. The method of claim 6 wherein the metal material comprises tungsten.

8. The method of claim 1 wherein the metal oxide is directly against the metal material.

9. The method of claim 1 wherein the metal oxide is not directly against the metal material.

10. The method of claim 9 wherein the metal oxide and the metal material are everywhere separated by insulator material that is of different composition from that of the metal oxide and that of the metal material.

11. The method of claim 1 comprising insulator material that is of different composition from that of the metal oxide and that of the metal material between the metal oxide and the metal material.

12. The method of claim 1 comprising:
rails that are individually between immediately-laterally-adjacent of the memory-block regions, the rails comprising the sacrificial material that comprises the metal oxide directly above the metal material; and
forming trenches into the upper portion to the rails and removing the sacrificial material of the rails through the trenches.

13. The method of claim 12 comprising insulator material that is of different composition from that of the metal oxide and that of the metal material between the metal oxide and the metal material in the plugs and in the rails.

14. The method of claim 13 wherein the metal oxide and the metal material are everywhere separated by the insulator material in the rails and in the plugs.

15. The method of claim 1 wherein the stack in the memory-block regions comprises a first vertical stack, and further comprising:
forming a second vertical stack aside the first vertical stack, the second vertical stack comprising an upper portion directly above a lower portion, the upper portion in the second vertical stack comprising vertically-alternating tiers that are of different composition relative one another, the lower portion in the second vertical stack comprising dummy plugs that comprise the metal oxide directly above the metal material, the dummy plugs remaining in a finished circuitry construction that comprises the memory array.

16. The method of claim 15 comprising forming the second vertical stack to comprise dummy rails comprising the metal oxide directly above the metal material, the dummy rails remaining in the finished circuitry construction.

17. The method of claim 15 wherein the channel-material strings and the channel-material string are operative and further comprising forming a dummy channel-material string directly above individual of the dummy plugs.

18. The method of claim 17 wherein the dummy channel-material string does not extend to its dummy plug.

19. The method of claim 1 wherein the stack in the memory-block regions comprises a first vertical stack, and further comprising:
forming a second vertical stack aside the first vertical stack, the second vertical stack comprising an upper portion directly above a lower portion, the upper portion in the second vertical stack comprising vertically-alternating tiers that are of different composition relative one another, the lower portion in the second vertical stack comprising dummy rails comprising the metal oxide directly above the metal material, the dummy rails remaining in a finished circuitry construction that comprises the memory array.

20. A method used in forming a memory array comprising strings of memory cells, comprising:
forming a lower portion of a stack that will comprise vertically-alternating first tiers and second tiers on a substrate, the stack comprising laterally-spaced memory-block regions, the lower portion comprising rails that are individually between immediately-laterally-adjacent of the memory-block regions, the rails comprising sacrificial material that comprises metal oxide directly above metal material, the metal oxide and the metal material comprising different compositions relative one another;
forming the vertically-alternating first tiers and second tiers of an upper portion of the stack directly above the lower portion, material of the first tiers being of different composition from material of the second tiers;
forming trenches into the upper portion to the rails and removing the sacrificial material of the rails through the trenches; and
forming channel-material strings that extend through the first tiers and the second tiers in the memory-block regions.

21. The method of claim 20 wherein the metal material comprises a metal oxide.

22. The method of claim 20 wherein the metal material does not comprise a metal oxide.

23. The method of claim 20 wherein the metal material comprises at least one of an elemental-form metal, a metal nitride, and a metal silicide.

24. The method of claim 20 wherein the metal oxide comprises at least one of an aluminum oxide, a tungsten oxide, a hafnium oxide, a hafnium aluminum oxide, and a tantalum oxide.

25. The method of claim 24 wherein the metal oxide comprises aluminum oxide.

26. The method of claim 20 wherein the metal oxide and the metal material are everywhere separated by insulator material that is of different composition from that of the metal oxide and that of the metal material.

27. The method of claim 20 wherein the stack in the memory-block regions comprises a first vertical stack, and further comprising:
forming a second vertical stack aside the first vertical stack, the second vertical stack comprising an upper portion directly above a lower portion, the upper portion in the second vertical stack comprising vertically-alternating tiers that are of different composition relative one another, the lower portion in the second vertical stack comprising dummy plugs that comprise the metal oxide directly above the metal material, the dummy plugs remaining in a finished circuitry construction that comprises the memory array.

28. The method of claim 20 wherein the stack in the memory-block regions comprises a first vertical stack, and further comprising:
forming a second vertical stack aside the first vertical stack, the second vertical stack comprising an upper portion directly above a lower portion, the upper portion in the second vertical stack comprising vertically-alternating tiers that are of different composition relative one another, the lower portion in the second vertical stack comprising dummy rails comprising the metal oxide directly above the metal material, the dummy rails remaining in a finished circuitry construction that comprises the memory array.

29. A memory array comprising strings of memory cells, comprising:
laterally-spaced memory blocks individually comprising a first vertical stack comprising vertically-alternating insulative tiers and conductive tiers, strings of memory cells comprising channel-material strings that extend through the insulative tiers and the conductive tiers; and
a second vertical stack aside the first vertical stack, the second vertical stack comprising an upper portion directly above a lower portion, the upper portion comprising vertically-alternating tiers that are of different composition relative one another, the lower portion comprising dummy plugs that comprise metal oxide directly above metal material, the metal oxide and the metal material comprising different compositions relative one another.

30-41. (canceled)

42. A memory array comprising strings of memory cells, comprising:
laterally-spaced memory blocks individually comprising a first vertical stack comprising vertically-alternating insulative tiers and conductive tiers, strings of memory cells comprising channel-material strings that extend through the insulative tiers and the conductive tiers; and
a second vertical stack aside the first vertical stack, the second vertical stack comprising an upper portion directly above a lower portion, the upper portion comprising vertically-alternating tiers that are of different composition relative one another, the lower portion comprising dummy rails comprising metal oxide directly above metal material, the metal oxide and the metal material comprising different compositions relative one another.

43-51. (canceled)
